(19) United States
(12) Patent Application Publication
(10) Pub. No.: US 2014/0099798 A1
(43) Pub. Date: Apr. 10, 2014

(54) UV-Curing Apparatus Provided With Wavelength-Tuned Excimer Lamp and Method of Processing Semiconductor Substrate Using Same

(71) Applicant: ASM IP HOLDING B.V., Almere (NL)

(72) Inventor: Naoto Tsuji, Tokyo (JP)

(73) Assignee: ASM IP HOLDING B.V., Almere (NL)

(21) Appl. No.: 13/646,471

(22) Filed: Oct. 5, 2012

(51) Int. Cl. H01L 21/268

(52) U.S. Cl. CPC H01L 21/268
USPC 438/795; 250/453.11

(57) ABSTRACT

A UV irradiation apparatus for processing a semiconductor substrate includes: a UV lamp unit having at least one dielectric barrier discharge excimer lamp which is constituted by a luminous tube containing a rare gas wherein an inner surface of the luminous tube is coated with a fluorescent substance having a peak emission spectrum in a wavelength range of 190 nm to 350 nm; and a reaction chamber disposed under the UV lamp unit and connected thereto via a transmission window.

### BACKGROUND OF THE INVENTION

1. Field of the Invention

The present invention generally relates to a UV light irradiating apparatus and a method for irradiating a semiconductor substrate.

2. Description of the Related Art

In general, UV irradiation apparatuses have been used for the quality modification of various processing targets via ultraviolet light and preparation of substances using photochemical reaction. With the recent trend for higher integration of devices, which requires finer wiring designs and multi-layer wiring structures, it is essential to reduce the inter-layer capacitance to make the devices operate faster while consuming less power. Low-k (low dielectric constant film) materials are used to reduce the inter-layer capacitance, but these materials not only lower the dielectric constant, but also reduce the mechanical strength (EM: elastic modulus), and are vulnerable to stress received after the CMP, wire bonding, and packaging post-processes. One way to improve the aforementioned problems is to irradiate UV light to cure the low-k material and thereby improve its mechanical strength (refer to U.S. Pat. No. 6,759,098 and U.S. Pat. No. 6,296,909, for example).

UV irradiation causes the low-k material to shrink and cure, allowing its mechanical strength (EM) to be improved by 50 to 200%.

Also, porogen materials introduced to the film can be decomposed and/or removed by means of UV irradiation (or heating, plasma or electron beam) to lower the dielectric constant of the film while curing the film at the same time (refer to U.S. Pat. No. 6,583,048, U.S. Pat. No. 6,846,515 and U.S. Pat. No. 7,098,149, for example).

On the other hand, photo CVD based on photochemical reaction has been studied up to now as a way to respond to another demand stemming from the recent trend of highly integrated devices, and as a method to obtain various thin films free of heat or plasma damages by utilizing thermal CVD or PECVD-based film deposition processes.

### SUMMARY OF THE INVENTION

However, if a UV luminous tube is a dielectric barrier discharge excimer lamp, it is difficult to obtain the required wavelength at the required illuminance. By irradiating with a 172-nm Xe excimer lamp, sufficient illuminance can be achieved and porogen materials introduced to the SiOC film in the semiconductor substrate can be decomposed and/or removed to lower the dielectric constant of the film, while curing the film at the same time. However, sizes of voids formed in the film as a result of irradiation are small on average but widely distributed, and some voids are large in size, which results in a large rate of drop in film density. In addition, FT-IR measurement of change in the bonding state of film found that Si—CH₃ bonds, originally present in the film, are converted to Si—H bonds which are non-existent in the film in the beginning. It is also found that presence of Si—H bonds in the film cause the electrical characteristics of the device to slightly deteriorate. Also, irradiating this optical energy onto the processing target or into the reaction space requires the UV lamp and reaction space to be partitioned, for the following reasons, among others: 1) pressure and ambient gas in the reaction space must be controlled, 2) generated gas would contaminate the UV lamp; and 3) generated gas must be exhausted safely. For this partition plate, normally a UV light transmitting window made of synthetic quartz is used that allows optical energy to be transmitted therethrough. However, a 172-nm Xe excimer lamp generating high energy presents problems, such as negatively affecting the chemical bonding of quartz and causing the transmittance to drop.

On the other hand, if a high-pressure mercury lamp is used as the light source, there is no light of less than 200 nm in wavelength and the first luminescence peak occurs near 250 nm. Sizes of voids formed in the film when a high-pressure mercury lamp is used are somewhat large on average but only narrowly distributed and there are no large voids, and consequently the rate of drop in film density is small. FT-IR measurement of change in the bonding state of film found virtually no conversion to Si—H bonds which are non-existent in the film at the beginning. However, use of a high-pressure mercury lamp presents problems, such as the generation of heat due to unnecessary wavelengths which are not optimal for the process account for a majority of the overall output, which causes the temperature of the semiconductor substrate to rise significantly, or by approx. 20° C., and also requires large attached equipment including a power supply and cooling mechanism to support such large output and control the heat, leading to higher cost and a larger footprint.

Any discussion of problems and solutions involved in the related art such as those discussed above has been included in this disclosure solely for the purposes of providing a context for the present invention, and should not be taken as an admission that any or all of the discussion were known at the time the invention was made.

In an embodiment of the present invention, the UV luminous tube is a dielectric barrier discharge excimer lamp with rare gas charged inside, which has a peak spectrum in a wavelength range of 190 to 350 nm depending on the type of the fluorescent substance applied to the interior walls of the UV luminous tube. In other words, use of a dielectric barrier discharge excimer lamp being a Xe excimer lamp allows for output of any desired wavelength in a range of 172 nm or more (190 to 350 nm) to permit tuning of wavelengths to one effective for the process. There are no wavelengths corresponding to the heat ray range, which prevents unnecessary rise in semiconductor substrate/apparatus temperatures and keeps the process stable, and because no cooling mechanism is required and a low-output power supply can be used, the cost can be reduced. Furthermore, this lamp becomes stable quickly after it is turned on, unlike the conventional mercury lamp, and required energy can be produced instantly, and also this lamp can be used in flashing mode and steady irradiation mode, which eliminates the need for a shutter and allows the structure to be simplified.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description which follows.

### BRIEF DESCRIPTION OF THE DRAWINGS

These and other features of this invention will now be described with reference to the drawings of preferred embodiments which are intended to illustrate and not to limit the invention. The drawings are greatly simplified for illustrative purposes and are not necessarily to scale.

FIG. 1A and FIG. 1B are schematic views of UV irradiation apparatuses according to embodiments of the present invention.

FIG. 2 is a graph showing FT-IR spectra of films irradiated with UV light in Examples 1 to 6.

FIG. 3 illustrates a schematic longitudinal section view ((a) in FIG. 3) and a schematic cross section view ((b) in FIG. 3) according to an embodiment of the present invention.

FIG. 4 is a schematic view of a conventional UV irradiation apparatus.

### DETAILED DESCRIPTION OF EMBODIMENTS

In this disclosure, “gas” may include vaporized solid and/or liquid and may be constituted by a single gas or a mixture of gases. Gases can be supplied in sequence with or without overlap. In this disclosure, an article “a” refers to a species or a genus including multiple species. Further, in this disclosure, any two numbers of a variable can constitute an workable range of the variable as the workable range can be determined based on routine work, and any ranges indicated may include or exclude the endpoints. Additionally, any values of variables indicated may refer to precise values or approximate values and include equivalents, and may refer to average, median, representative, majority, etc. in some embodiments. In the present disclosure where conditions and/or structures are not specified, the skilled artisan in the art can readily provide such conditions and/or structures, in view of the present disclosure, as a matter of routine experimentation. In all of the disclosed embodiments, any element used in an embodiment can be replaced with any elements equivalent thereto, including those explicitly, necessarily, or inherently disclosed herein, for the intended purposes. Further, the present invention can equally be applied to apparatuses and methods. In this disclosure, any defined meanings do not necessarily exclude ordinary and customary meanings in some embodiments.

In the disclosure, “substantially zero” or the like may refer to an immaterial quantity, less than a detectable quantity, a quantity that does not materially affect the target or intended properties, or a quantity recognized by a skilled artisan as nearly zero, such that less than 10%, less than 5%, less than 1%, or any ranges thereof relative to the total in some embodiments.

Some embodiments of the present invention provide a UV irradiation apparatus for processing a semiconductor substrate, comprising: (i) a UV lamp unit comprising at least one dielectric barrier discharge excimer lamp for irradiating the substrate with UV light, which lamp is constituted by a luminous tube containing a rare gas wherein an inner surface of the luminous tube is coated with a fluorescent substance having a peak (maximum) emission spectrum in a wavelength range of 190 nm to 350 nm; and (ii) a reaction chamber for supporting and processing the substrate with the UV light, said reaction chamber being disposed under the UV lamp unit and connected thereto via a transmission window.

In some embodiments, the rare gas is at least one gas selected from the group consisting of He, Ne, Ar, Kr, Xe, and Rn. In a discharge plasma, atoms of the discharge gas are excited by high-energy electrons, thereby instantaneously becoming an excimer state (indicated by *). When the excimer state returns to the ground state, light having an emission spectrum specific to the type of excimer is emitted (excimer emission). The emission spectrum inside the luminous tube is determinative depending on the composition of the discharge gas. For example, the peak emission spectra of excimer Ar₂*, Kr₂*, Xe₂*, KrCl₂*, and XeCl₂* are 125 nm, 146 nm, 172 nm, 222 nm, and 308 nm, respectively. UV light generated inside the luminous tube is converted by the fluorescent substance formed on the inner wall of the luminous tube so as to adjust the emission spectrum of UV light emitted from the luminous tube. For example, UV light using excimer Xe₂* having a peak emission spectrum of 172 nm without a fluorescent substance may have integration problems such as conversion to Si—H bonds, low film density, wide distribution of pore sizes, etc. On the other hand, a high-pressure mercury lamp having a spectrum higher than 200 nm without a fluorescent substance may not have the above integration problems and thus has been used widely, but it has problems of generating heat, using high energy, requiring a cooling system, etc., since it has emission peaks in a range of 400 nm or higher.

In some embodiments, the fluorescent substance is at least one substance selected from the group consisting of LaPO₄:Nd, YPO₄:Nd, LuPO₄:Nd, LaPO₄:Pr, LaBO₃:Pr, YPO₄:Pr, YBO₄:Pr, LuPO₄:Pr, SrSiO₃:Pr, CaSO₄:Pr, (Ca,Mg)SO₄:Pr, La₂O₂S:Pr, Lu₂O₂S:Pr, YPO₄:Bi, (La,Mg)AlO₃:Ce, LaPO₄:Ce, YPO₄:Ce, (Mg,Ba)AlO₃:Ce, LaPO₄:(Gd,Pr), YBO₃:(Gd,Pr), SrB₄O₇:Eu, and BaSi₂O₅:Pb. For example, when excimer Xe₂* is used, the fluorescent substances emit light with the following peak emission spectra:

TABLE 1

| | Peak emission | |
|---|---|---|
| Fluorescent substance | spectrum | |
| Neodymium-activated lanthanum phosphate (LaPO4: Nd) | 190 | nm |
| Neodymium-activated yttrium phosphate (YPO4: Nd) | 190 | nm |
| Neodymium-activated lutetium phosphate (LuPO4: Nd) | 190 | nm |
| Praseodymium-activated lanthanum phosphate | 230 | nm |
| (LaPO4: Pr) | | |
| Praseodymium-activated lanthanum borate (LaBO3: Pr) | 200-300 | nm |
| Praseodymium-activated yttrium phosphate (YPO4: Pr) | 250 | nm |
| Praseodymium-activated yttrium borate (YBO4: Pr) | 200-300 | nm |
| Praseodymium-activated lutetium phosphate (LuPO4: Pr) | 200-300 | nm |
| Praseodymium-activated strontium silicate (SrSiO3: Pr) | 290 | nm |
| Praseodymium-activated calcium sulfide (CaSO4: Pr) | 230 | nm |
| Praseodymium-activated calcium magnesium sulfide | 250 | nm |
| {(Ca, Mg) SO4: Pr} | | |
| Praseodymium-activated lanthanum oxysulphide | 290 | nm |
| (La2O2S: Pr) | | |
| Praseodymium-activated lutetium oxysulphide | 290 | nm |
| (Lu2O2S: Pr) | | |
| Bismuth-activated yttrium phosphate (YPO4: Bi) | 200-300 | nm |
| Cerium-activated lanthanum magnesium aluminate | 350 | nm |
| {(La, Mg) AlO3: Ce} | | |
| Cerium-activated lanthanum phosphate (LaPO4: Ce) | 320 | nm |
| Cerium-activated yttrium phosphate (YPO4: Ce) | 350 | nm |
| Cerium-activated magnesium barium aluminate | 300-400 | nm |
| {(Mg, Ba) AlO3: Ce} | | |
| Praseodymium & gadolinium-activated lanthanum | 320 | nm |
| phosphate (LaPO4: Gd, Pr) | | |
| Praseodymium & gadolinium-activated yttrium | 320 | nm |
| borate (YBO3: Gd, Pr) | | |
| Europium-activated strontium borate (SrB4O7: Eu) | 350 | nm |
| Lead-activated barium silicate (BaSi2O5: Pb) | 350 | nm |

When light is absorbed by the fluorescent pigment, its electrons are excited and migrate from the stationary state to the energy level called “excited electronic singlet state” where the amount of energy needed to cause this migration varies with each fluorescent pigment (indicated by “Excitation (Ex)”), and because the fluorescent pigment changes its internal structure and consequently discharges some of its absorbed energy in the form of heat, this state lasts for only 1 to 10 nanoseconds, after which the electrons settle at the lower, stable energy level called “relaxed excited electronic singlet state.” When the electrons subsequently return to their ground state, they discharge the remaining energy, or Emission (Em), as fluorescence. The wavelength of the excitation side varies depending on the type of rare gas sealed in the lamp, and the same fluorescence is emitted if the relationship of this and the energy difference between orbits remains the same. By sealing an appropriate type of rare gas in the lamp and combining it with an appropriate fluorescent pigment, the lamp can have a desired peak spectrum in a range of 190 to 350 nm.

In some embodiments, the at least one dielectric barrier discharge excimer lamp has a power of 5 W/cm² or less (e.g., less than 4 W/cm², 3 W/cm², 2 W/cm², or 1 W/cm²) per area of the substrate, which power is sufficient (e.g., at least 0.1 W/cm², 0.5 W/cm², 1 W/cm²) to decompose and remove a porogen material from a film formed on the substrate. In some embodiments, ranges between any two numbers of the foregoing may be used. Since the UV light does not have a heat generating peak spectrum in a range of 400 nm or higher, for example, the emission power can be low so as to inhibit raising the temperature of the substrate. In some embodiments, the at least one dielectric barrier discharge excimer lamp emits substantially no light having as wavelength of 400 nm or higher. As a result, in some embodiments, the at least one dielectric barrier discharge excimer lamp is provided with no cooling jacket wherein a coolant circulates, eliminating a cooling system. In some embodiments, the footprint of a power/cooling system can be as low as several percent of that of a high-pressure mercury lamp.

In some embodiments, a layer of the fluorescent substance which coats the inner surface of the luminous tube has a thickness of 1 μm to 100 μm (typically, e.g., 5 μm to 80 μm, 10 μm to 50 μm). The fluorescent substance can be applied as a single layer or two or more layers of different fluorescent substances. Any suitable coating methods can be used to apply the fluorescent substance on the inner surface of the luminous tube. In some embodiments, the interior of the luminous tube has a pressure of 100 Torr to 1,000 Torr (typically, e.g., 200 Torr to 800 Torr, 300 Torr to 600 Torr). In some embodiments, a distance between the at least one dielectric barrier discharge excimer lamp and the substrate is less than 400 mm, typically, e.g., 5 mm to 350 mm.

Since the excimer lamp is highly responsive, i.e., can emit UV light instantaneously, in some embodiments, the at least one dielectric barrier discharge excimer lamp emits UV light in pulses at predetermined intervals, without using a shutter.

In some embodiments, the luminous tube has a double tube structure (e.g., a double-walled quartz glass) comprising an inner tube and an outer tube enclosing the inner tube, both being made of a dielectric material, wherein the innermost surface of the inner tube is provided with a high voltage (HV) electrode, the outermost surface of the outer tube is provided with a transparent electrode, and the inner wall of the outer tube is coated with the fluorescent substance.

In some embodiments, the luminous tube has a single tube structure comprising a tube containing the rare gas and made of a dielectric material, wherein the outer surface of the tube is provided with a pair of external electrodes disposed opposite to each other and extending along the length of the tube, and the inner surface of the tube is coated with the fluorescent substance.

In another aspect, some embodiments provide a method for processing a semiconductor substrate using any of the foregoing UV irradiation apparatuses, comprising: (a) loading a semiconductor substrate in the reaction chamber, said semiconductor substrate having a porogen-containing SiOC film formed thereon; (b) exposing the porogen-containing SiOC film to UV light emitted from the at least one dielectric barrier discharge excimer lamp to decompose and remove porogen materials from the film so as to render the film porous, while keeping an increase in temperature of the substrate within 5° C. or less (e.g., 4° C. or less, 3° C. or less, 2° C. or less, or substantially no increase of temperature) without using a coolant circulating around the luminous tube; and (c) unloading the semiconductor substrate with the porous SiOC film formed thereon from the reaction chamber. Forming the porogen-containing SiOC film on the substrate can be accomplished by a skilled artisan using any suitable methods including those disclosed in U.S. Pat. No. 6,583,048, U.S. Pat. No. 6,846,515, and U.S. Pat. No. 7,098,149, each disclosure of which is herein incorporated by reference in its entirety. In some embodiments, the temperature of the substrate is controlled at 300° C. to 450° C.

In some embodiments, the at least one dielectric barrier discharge excimer lamp has a power of 5 W/cm² or less per area of the substrate, as described above.

In some embodiments, pores present in the porous SiOC film have an average pore size of 0.9 nm±10% and a full width at half maximum (FWHM) of 0.4 nm±50%. In some embodiments, the porous SiOC film has substantially no Si—H bond. In some embodiments, the porous SiOC film has a film density of about 1.17 g/cm³.

The embodiments will be explained with respect to preferred embodiments. However, the present invention is not limited to the preferred embodiments

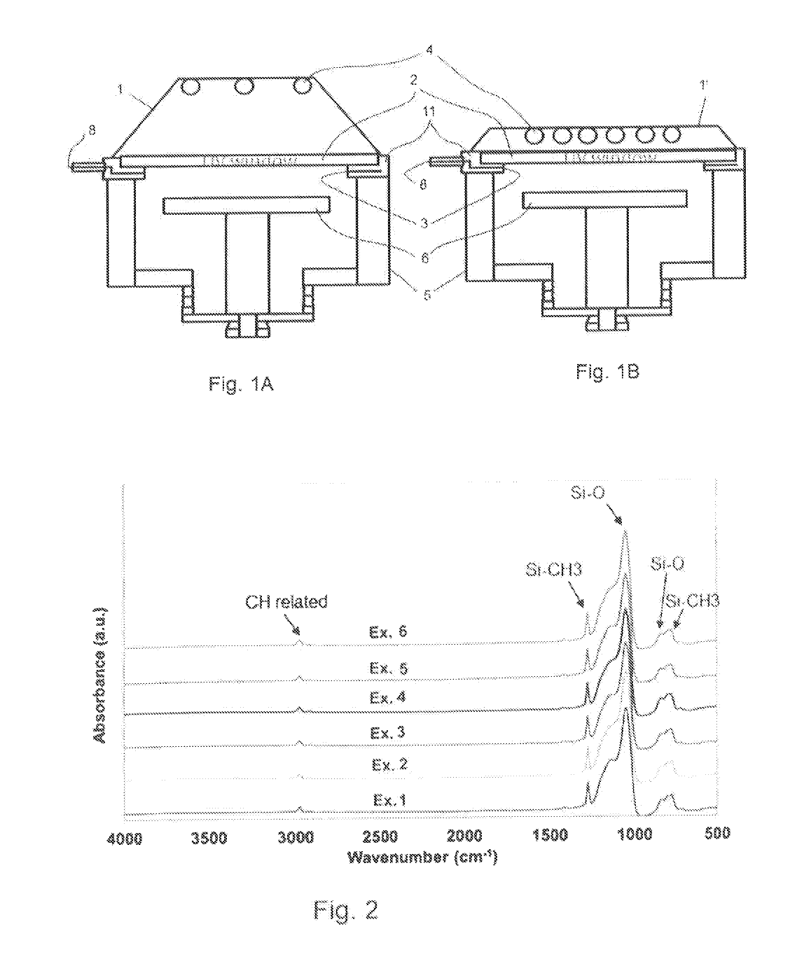

FIG. 1A and FIG. 1B are schematic views of UV irradiation apparatuses according to embodiments of the present invention.

The apparatus in FIG. 1A comprises a reaction chamber 5 which can be controlled from vacuum to near atmosphere, and UV irradiation unit 1 installed above the chamber. In other words, this apparatus is equipped with a UV lamp 4, irradiation window 2, gas inlet 3, UV irradiation chamber 1, susceptor heater 6, and exhaust port (not illustrated). The irradiation window 2 is installed on a flange 11, while the reaction chamber 5 and UV irradiation unit 1 are separated by the irradiation window and connected via the flange 11. The gas inlet 3 is a nozzle provided along a ring-shaped gas line provided in the flange 11 at a specific interval, and extending inward, where the inlet is structured in such a way that gas is discharged uniformly from the circumferential direction toward the inside (only the nozzle is shown in the figure). To be specific, the gas inlet is laid via the flange 11 and multiple units of this gas inlet are provided in a symmetrical layout to generate a uniform processing ambience. Also, gas is supplied to the ring-shaped gas line via a line 8 from an external gas supply. It should be noted that the apparatus is not at all limited to this figure as long as it can irradiate UV light.

The apparatus in FIG. 1B has a lower UV irradiation unit 1′ and consequently the distance between the UV lamp 4 and susceptor heater 6 is much shorter than with the apparatus in FIG. 1A. In this embodiment, heat generation from the UV lamp 4 is suppressed, so bringing the UV lamp closer to the irradiation window does not cause heat to generate.

In addition, the UV lamp, irradiation window, and susceptor heater are installed in parallel with and opposing one another. The UV lamp can emit UV light continuously or in pulses. The irradiation window 2 is provided to achieve uniform UV irradiation by cutting off the reaction chamber from atmosphere while allowing UV light to transmit through said window. For the UV lamp 4 in the UV irradiation unit, multiple tube-shaped lamps can be placed in parallel, with its illuminants arranged in an appropriate manner as shown in FIG. 1 to achieve uniform illuminance, for example, while a reflection plate (not illustrated) (similar to a shade on the UV lamp) is provided to allow the UV light from each UV lamp to be irradiated properly onto the thin film on the substrate, with the angle of this reflection plate pre-adjusted to achieve uniform illuminance. The UV lamp 4 is structured to allow for easy removal and replacement. For the reflection plate, the structure disclosed in U.S. Patent Laid-open No. 2008/0230721 can be adopted, but for other structures, such as the structure of the exhaust port, it is also possible to adopt the structure disclosed in U.S. Patent Laid-open No. 2008/0230721, the disclosures of which are herein incorporated by reference in their entirety.

Also, the pressure in the reaction chamber 5 is adjusted using a pressure control valve (not illustrated) provided at the exhaust port. The UV irradiation unit is also a sealed space, but it has an inlet and outlet for taking in and discharging purge gas (not illustrated) (the unit is constantly purged with atmosphere).

An example of the UV irradiation processing steps is shown below, but it should be noted that the present invention is not at all limited to these embodiments. First, an ambience of a gas selected from Ar, CO, CO₂, C₂H₄, CH₄, H₂, He, Kr, Ne, N₂, O₂, Xe, alcohol gases, and organic gases, pressurized to approx. 0.1 Torr to near atmospheric pressure (including 1 Torr, 10 Torr, 50 Torr, 100 Torr, 1000 Torr and all pressures in between, but preferably between 1 and 50 Torr), is created inside the chamber 5, after which a semiconductor substrate, being the processing target, is loaded from the load lock chamber via the gate valve and placed on the heater 6 that has been set to a temperature between approx. 0° C. and 650° C. (including 10° C., 50° C., 100° C., 200° C., 300° C., 400° C., 500° C., 600° C. and all temperatures in between, but preferably between 300° C. and 450° C.), and UV light of a wavelength of 200 nm to 400 nm (including 150 nm, 200 nm, 250 nm, 300 nm, 350 nm and all wavelengths in between, but preferably approx. 250 nm) is irradiated, at an output of approx. 1 mW/cm² to 1000 mW/cm² (including 10 mW/cm², 50 mW/cm², 100 mW/cm², 200 mW/cm², 500 mW/cm², 800 mW/cm², and all outputs in between, but preferably between 5 and 300 mW/cm²), onto the thin film on the semiconductor substrate from the UV lamp 4 at an appropriate distance (5 to 300 mm) either continuously or in pulses of approx. 1 Hz to 1000 Hz (including 10 Hz, 100 Hz, 200 Hz, 500 Hz and all frequencies in between). The irradiation time is approx. 1 second to 20 minutes (including 5 seconds, 10 seconds, 20 seconds, 50 seconds, 100 seconds, 200 seconds, 500 seconds, 1000 seconds and all durations in between). The chamber 1 is evacuated from an exhaust port (not illustrated).

This semiconductor manufacturing apparatus performs the above series of processing steps, including introduction of gas, irradiation of UV light, stopping of irradiation, and stopping of gas, according to an automatic sequence.

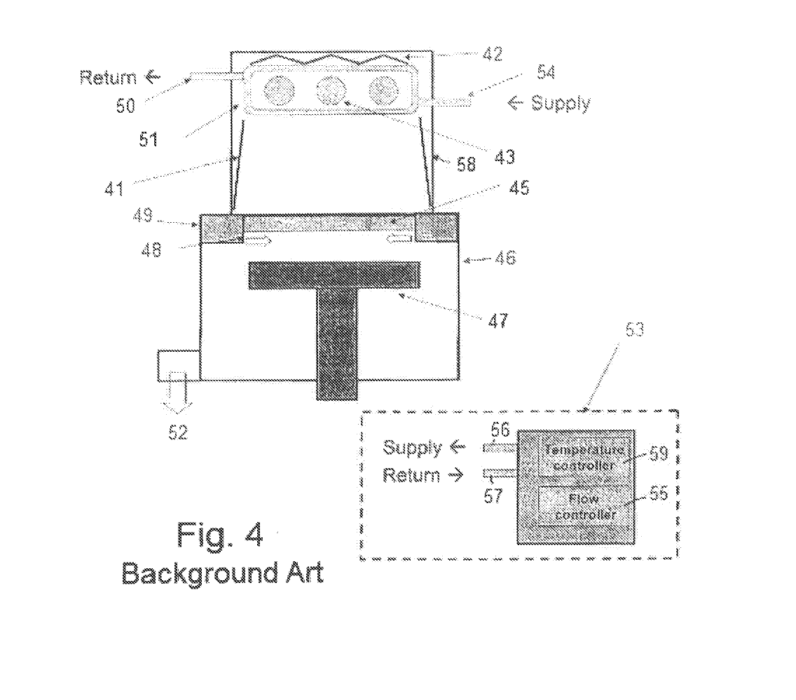

As illustrated in FIGS. 1A and 1B, in some embodiments, there is no cooling system provided in the apparatus, since the UV lamp having an adjusted or tuned emission peak spectrum for suppressing heat generation. FIG. 4 is a schematic view of a conventional UV irradiation apparatus. The UV irradiation apparatus shown in FIG. 4 comprises a UV unit 58, water-cooled filter 51, transmission window 45, gas introduction ring 49, reactor chamber 46, heater table 47, and vacuum pump 52. The gas introduction ring 49 has multiple gas outlet ports 48, through which gas is discharged toward the center between the arrows. A cold mirror 41 is fitted along the interior walls of the UV unit 58 to transmit IR light but cause UV light to reflect upon the mirror, so that UV light will go through the transmission window 45 effectively. Another cold mirror 42 is also placed above a UV lamp 43 for the same purpose. The water-cooled fitter 51 has a cooling-water inlet 54 and cooling-water outlet 50, where the cooling-water inlet 54 is connected to a cooling-water supply port 56 on a chiller unit (heat exchanger) 53 to allow cooling water in the chiller unit 53 to be supplied into the water-cooled filter 51. The cooling-water outlet 50 is connected to a cooling-water return port 57 on the chiller unit 53 to return cooling water to the chiller unit 53 after it has passed through the water-cooled filter 51. The chiller unit 53 has a temperature controller 59 and a flow controller 55 to control the temperature and flow rate of cooling water. As illustrated above, a typical conventional UV irradiation apparatus with high-pressure mercury lamps is provided with a cooling system comprised of a chiller unit, a water-cooled filter (water jacket) enclosing the lamps, and water-supply lines connecting the chiller unit and the water-cooled filter. In contrast, in some embodiments of the present invention, none of the components is provided in the UV irradiation apparatus, lowering the equipment cost and the footprint of the apparatus.

In some embodiments, the excimer lamp is a dielectric barrier discharge lamp constituted by a single-wall tube or double-walled tube comprising an electrode covered with a dielectric material such as synthetic quartz and another electrode covered with a dielectric material such as synthetic quartz, wherein the dielectric materials constitute a luminous tube, and an inner surface of the dielectric material(s) is coated with a fluorescent substance. The luminous tube contains a rare gas, and when power is applied between the one electrode and the another electrode, the rare gas is excited and a plasma is generated inside the luminous tube, emitting UV light through the wall of the luminous tube. In some embodiments, the electrode from which UV light is emitted is a transparent electrode or a mesh-type metal electrode so that UV light can pass through it. Typically, the other electrode is an HV (high voltage) electrode or plate-type metal electrode.

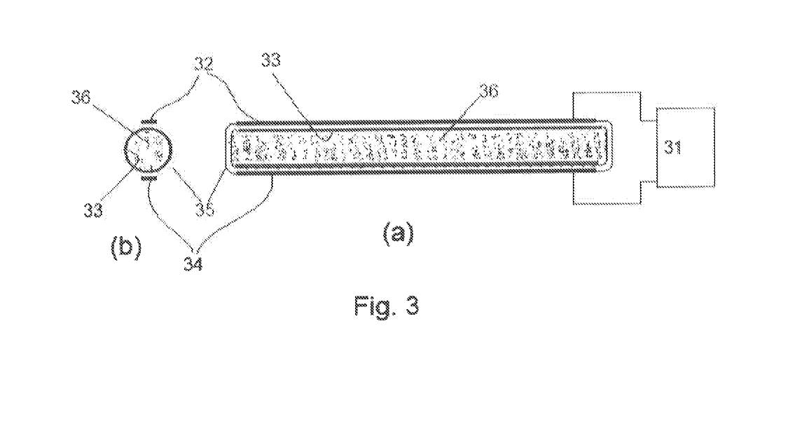

In some embodiments, the luminous tube has a structure illustrated in FIG. 3. FIG. 3 illustrates a schematic longitudinal section view ((a) in FIG. 3 as viewed from above) and a schematic cross section view ((b) in FIG. 3) according to an embodiment of the present invention. As illustrated in (a) and (b) in FIG. 3, this luminous tube is a single tube 35 made of a dielectric material such as synthetic quartz, forming the closed interior which contains a rare gas 36 causing dielectric barrier discharge. The outer surface of the tube 35 is provided with a pair of external electrodes 32, 34 (conductive resin or metal) disposed opposite to each other and extending along the length of the tube, and the inner wall of the tube 35 is coated with a fluorescent substance 33. Power is applied from an RF power source 31 (inverter) between the electrodes 32, 34 so that a dielectric barrier discharge occurs in the interior of the tube.

In some embodiments, the tube adapted to be installed in a single chamber module for a 300-mm wafer has an external diameter of 5 mm to 80 mm and an effective length of 300 mm to 500 mm (the length of a portion emitting light uniformly). In some embodiments, the tube adapted to be installed in a single chamber module for a 450-mm wafer has an external diameter of 5 mm to 80 mm and an effective length of 400 mm to 600 mm. In some embodiments, the tube adapted to be installed in a dual chamber module for a 300-mm wafer has an external diameter of 5 mm to 80 mm and an effective length of 800 mm to 1,000 mm. In some embodiments, the tube adapted to be installed in a dual chamber module for a 450-mm wafer has an external diameter of 5 mm to 80 mm and an effective length of 1,000 mm to 1,400 mm. In some embodiments, the shape of the cross section of the tube is a circle, and alternatively, in other embodiments, the shape of the cross section of the tube is a triangle, square, rectangle, rhombus, parallelogram, trapezoid, pentagon, hexagon, heptagon, or octagon. In some embodiments, the tube is a straight tube or a circular tube, and tubes of different cross sections, shapes, luminescence intensities can be used in combination.

### EXAMPLES

### Examples 1 to 6

A substrate (300 mm in diameter) having a dielectric film containing a porogen material formed thereon was loaded in a UV irradiation apparatus illustrated in FIG. 1B wherein dielectric barrier discharge excimer lamps illustrated in FIG. 3 were installed. The tubes of the lamps contained Xe gas, and the fluorescent substances applied on an inner surface of the tubes are shown in Table 2 below. Table 2 also shows alternatively usable fluorescent substances. No water-cooling system was used. The dielectric film formed on the substrate was cured in the apparatus using UV light emitted from the lamps under the following conditions:

Pressure: 5 Torr

Supplied gas: Nitrogen gas

Temperature: 400° C.

Distance between the substrate and the lamps: 100 mm

Power applied to the lamps: 4 W/cm²

Irradiation duration: 60 to 1,200 seconds

TABLE 2

| | Emission | Fluorescent | |
|---|---|---|---|
| | peak spectrum | substance | Alternative |
| Ex. 1 | 190 nm | LaPO₄: Nd | YPO₄: Nd, LuPO₄: Nd |
| Ex. 2 | 230 nm | LaPO₄: Pr | CaSO₄: Pr |
| Ex. 3 | 250 nm | YBO₃: Pr | (Ca, Mg)SO₄: Pr, YPO₄: Pr |
| Ex. 4 | 290 nm | SrSiO₃: Pr | La₂O₂S: Pr, Lu₂O₂S: Pr |
| Ex. 5 | 320 nm | LaPO₄: Ce | LaPO₄: (Gd, Pr), |
| | | | YBO₃: (Gd, Pr) |
| Ex. 6 | 350 nm | YPO₄: Ce | (La, Mg)AlO₃: Ce, |
| | | | BaSi₂O₅: Pb, SrB₄O₇: Eu |

### Comparative Examples 1

As a comparative example, the apparatus and conditions set forth in Examples 1 to 6 were used except that Xe excimer lamps without the fluorescent substance (the emission peak spectrum was 172 nm) were used in place of the excimer lamps used in Examples 1 to 6.

### Comparative Example 2

As a another comparative example, the apparatus illustrated in FIG. 4 with high-pressure mercury lamps (the emission peak spectrum was 200 nm or higher) was used with a water-cooling system, and curing was conducted in the same manner as in Examples 1 to 6 except that the distance between the substrate and the lamps was 300 mm, and power applied to the lamps was 12 W/cm².

The films on the substrates before the curing had a dielectric constant of about 2.8 and an elastic modulus of about 4 GPa. The curing duration was adjusted so that after the curing, the dielectric constant and the elastic modulus of the films were changed to about 2.4 and about 8 GPa, respectively, in all of Examples 1 to 6 and Comparative Examples 1 and 2. The films after the curing were analyzed to determine their average pore size (measured by X-ray reflection (XRR)), pore size distribution (FWHM: full width at half maximum) (measured by small angle X-ray scattering (SAXS)), and film density. The films were also analyzed to determine whether the bonds in the films were converted to Si—H bonds using FT-IR spectra. Additionally, an increase of temperature of the substrates during the curing was measured. The results are shown in Table 3.

TABLE 3

| | Aver- | Pore size | | | |
|---|---|---|---|---|---|
| | age | distri- | | Conver- | Temper- |
| Emission peak | pore | bution; | Film | sion | ature |
| spectrum in | size | FWHM | density | to Si—H | increase |
| parentheses | (nm) | (nm) | (g/cm¹) | bonds | (° C.) |
| Comparative Ex. 1 | 0.8 | 0.7 | 1.14 | Detected | <5 |
| Comparative Ex. 2 | 0.9 | 0.4 | 1.17 | None | 20 |
| Example 1 (190 nm) | 0.9 | 0.4 | 1.17 | None | <5 |
| Example 2 (230 nm) | 0.9 | 0.4 | 1.17 | None | <5 |
| Example 3 (250 nm) | 0.9 | 0.4 | 1.17 | None | <5 |
| Example 4 (290 nm) | 0.9 | 0.4 | 1.17 | None | <5 |
| Example 5 (320 nm) | 0.9 | 0.4 | 1.17 | None | <5 |
| Example 6 (350 nm) | 0.9 | 0.4 | 1.17 | None | <5 |

The results of FT-IR spectra of films irradiated with UV light in Examples 1 to 6 are shown in FIG. 2. As shown in FIG. 2, no Si—H bonds are detected in Examples 1 to 6.

As described above, with the films obtained in Examples 1 to 6, sizes of pores formed in the film were somewhat large on average but only narrowly distributed and there were no large pores, as shown in Table 3, and consequently the rate of drop in the density of the obtained film was small. Also FT-IR measurement of change in the bonding state of film found virtually no conversion to Si—H bonds which were non-existent in the film at the beginning as shown in FIG. 2. In other words, these examples provided excellent films equivalent to those obtained with the high-pressure mercury lamp. In addition, the power supplied to the light source was less than one-half that of the high-pressure mercury lamp in equivalent semiconductor substrate area (per unit area) and, as shown in Table 3, the semiconductor substrate temperature rose by less than 5° C. compared to approx. 20° C. experienced with a high-pressure mercury lamp, while the power supply footprint was also a fraction of the footprint required by the high-pressure mercury lamp, and a cooling mechanism was eliminated; the apparatus turned out to be very cost-effective.

It will be understood by those of skill in the art that numerous and various modifications can be made without departing from the spirit of the present invention. Therefore, it should be clearly understood that the forms of the present invention are illustrative only and are not intended to limit the scope of the present invention.

We/I claim:

1. A UV irradiation apparatus for processing a semiconductor substrate, comprising:
a UV lamp unit comprising at least one dielectric barrier discharge excimer lamp for irradiating the substrate with UV light, which lamp is constituted by a luminous tube containing a rare gas wherein an inner surface of the luminous tube is coated with a fluorescent substance having a peak emission spectrum in a wavelength range of 190 nm to 350 nm; and
a reaction chamber for supporting the substrate and processing the same with the UV light, said reaction chamber being disposed under the UV lamp unit and connected thereto via a transmission window.

2. The UV irradiation apparatus according to claim 1, wherein the rare gas is at least one gas selected from the group consisting of He, Ne, Ar, Kr, Xe, and Rn.

3. The UV irradiation apparatus according to claim 1, wherein the fluorescent substance is at least one substance selected from the group consisting of LaPO₄:Nd, YPO₄:Nd, LuPO₄:Nd, LaPO₄:Pr, LaBO₃:Pr, YPO₄:Pr, YBO₄:Pr, LuPO₄:Pr, SrSiO₃:Pr, CaSO₄:Pr, (Ca,Mg)SO₄:Pr, La₂O₂S:Pr, Lu₂O₂S:Pr, YPO₄:Bi, (La,Mg)AlO₃:Ce, LaPO₄:Ce, YPO₄:Ce, (Mg,Ba)AlO₃:Ce, LaPO₄:(Gd,Pr), YBO₃:(Gd,Pr), SrB₄O₇;Eu, and BaSi₂O₅:Pb.

4. The UV irradiation apparatus according to claim 1, wherein the at least one dielectric barrier discharge excimer lamp has a power of 5 W/cm² or less per area of the substrate, which power is sufficient to decompose and remove a porogen material from a film formed on the substrate.

5. The UV irradiation apparatus according to claim 1, wherein the at least one dielectric barrier discharge excimer lamp emits substantially no light having a wavelength of 400 nm or higher.

6. The UV irradiation apparatus according to claim 1, wherein the at least one dielectric harrier discharge excimer lamp is provided with no cooling jacket wherein a coolant circulates.

7. The UV irradiation apparatus according to claim 1, wherein a layer of the fluorescent substance which coats the inner surface of the luminous tube has a thickness of 1 μm to 100 μm.

8. The UV irradiation apparatus according to claim 1, wherein the interior of the luminous tube has a pressure of 100 Torr to 1,000 Torr.

9. The UV irradiation apparatus according to claim 1, wherein the at least one dielectric harrier discharge excimer lamp emits UV light in pulses at predetermined intervals.

10. The UV irradiation apparatus according to claim 1, wherein a distance between the at least one dielectric barrier discharge excimer lamp and the substrate is less than 200 mm.

11. The UV irradiation apparatus according to claim 1, wherein the luminous tube has a single tube structure comprising a tube containing the rare gas and made of a dielectric material, wherein the outer surface of the tube is provided with a pair of external electrodes disposed opposite to each other and extending along the length of the tube, and the inner surface of the tube is coated with the fluorescent substance.

12. A method for processing a semiconductor substrate using the UV irradiation apparatus according to claim 1, comprising:
loading a semiconductor substrate in the reaction chamber, said semiconductor substrate having a porogen-containing SiOC film formed thereon;
exposing the porogen-containing SiOC film to UV light emitted from the at least one dielectric barrier discharge excimer lamp to decompose and remove porogen materials from the film so as to render the film porous, while keeping an increase in temperature of the substrate within 5° C. or less without using a coolant circulating around the luminous tube; and
unloading the semiconductor substrate with the porous SiOC film formed thereon from the reaction chamber.

13. The method according to claim 12, wherein the at least one dielectric barrier discharge excimer lamp has a power of 5 W/cm² or less per area of the substrate.

14. The method according to claim 12, wherein pores present in the porous SiOC film have an average pore size of 0.9 nm±10% and a full width at half maximum (FWHM) of 0.4 nm±50%.

15. The method according to claim 12, wherein the porous SiOC film has substantially no Si—H bond.

16. The method according to claim 12, wherein the porous SiOC film has a film density of about 1.17 g/cm³.

17. The method according to claim 12, wherein the temperature of the substrate is controlled at 300° C. to 450° C.
